(19) United States
(12) Patent Application Publication
(10) Pub. No.: US 2025/0285667 A1
(43) Pub. Date: Sep. 11, 2025

(54) SELF-DESTRUCTIVE POLYMORPHIC LATCH FOR ERASING DATA STORED IN VOLATILE MEMORY DURING PHYSICAL ATTACKS

(71) Applicant: University of Florida Research Foundation, Incorporated, Gainesville, FL (US)

(72) Inventors: Domenic J. Forte, Gainesville, FL (US); Andrew John Cannon, Gainesville, FL (US); Tasnuva Farheen, Gainesville, FL (US); Sourav Roy, Gainesville, FL (US)

(21) Appl. No.: 19/025,487

(22) Filed: Jan. 16, 2025

Related U.S. Application Data
(60) Provisional application No. 63/561,983, filed on Mar. 6, 2024.

(51) Int. Cl. G11C 7/24

(52) U.S. Cl. CPC G11C 7/24

(57) ABSTRACT

A polymorphic latch comprising a pair of polymorphic gates that is configured in a D-latch, wherein a polymorphic gate of the pair of polymorphic gates comprises (i) a low voltage function and a high voltage function, (ii) a pull-down network (PDN) that is associated with the high voltage function, (iii) a pull-up network (PUN) that is coupled to the PDN, wherein the PUN is associated with the low voltage function, and (iv) one or more gating transistors that are configured to provide the PDN with a path to a ground; a pair of AND logic gates, wherein an output of an AND logic gate of the pair of AND logic gates is coupled to an input of the polymorphic gate; and an inverter coupled to an input of the AND logic gate.

### CROSS REFERENCE TO RELATED APPLICATION

This application claims the priority of U.S. Provisional Application No. 63/561,983, entitled “SELF-DESTRUCTIVE POLYMORPHIC LATCH FOR ERASING DATA STORED IN VOLATILE MEMORY DURING PHYSICAL ATTACKS,” filed on Mar. 6, 2024, the disclosure of which is hereby incorporated by reference in its entirety.

### GOVERNMENT SUPPORT

This invention was made with government support under 2150122 awarded by The National Science Foundation. The government has certain rights in the invention.

### TECHNICAL FIELD

Various embodiments of the present disclosure relate to protecting sensitive information stored in volatile memory, and more particularly to a polymorphic memory element that clears its data in response to changes in supply voltage caused by attacks.

### BACKGROUND

Secrets, such as cryptographic keys and obfuscation keys may be used in computing systems to protect sensitive and private information as well as intellectual property (IP). During conventional operation, such secrets may be stored in volatile memory devices, such as registers and SRAMs, which are vulnerable to active physical attacks whereby environmental parameters such as temperature, system clock, supply voltage, etc., may be manipulated to extract information. A traditional way to protect assets against such attacks may comprise using sensors that detect active physical attacks and trigger the destruction of secrets. However, this may require several thousand clock cycles to accomplish. Furthermore, traditional detection and destruction mechanisms may be implemented as separate circuitry, which can be identified and disabled by an attacker.

### BRIEF SUMMARY

Various embodiments described herein relate to polymorphic gates, latches, and/or registers for protecting sensitive information from attacks.

According to some embodiments, a polymorphic latch comprises a pair of polymorphic gates that is configured in a D-latch, wherein a polymorphic gate of the pair of polymorphic gates comprises: (i) a low voltage function and a high voltage function, (ii) a pull-down network (PDN) that is associated with the high voltage function, (iii) a pull-up network (PUN) that is coupled to the PDN, wherein the PUN is associated with the low voltage function, and (iv) one or more gating transistors that are configured to provide the PDN with a path to a ground; a pair of AND logic gates, wherein an output of an AND logic gate of the pair of AND logic gates is coupled to an input of the polymorphic gate; and an inverter coupled to an input of the AND logic gate.

In some embodiments, the low voltage function comprises a NAND gate operation. In some embodiments, the NAND gate operation comprises a forbidden state that is associated with a low clock signal. In some embodiments, the high voltage function comprises a NOR gate operation. In some embodiments, the low voltage function comprises a function associated with providing a supply voltage to the pair of polymorphic gates, wherein the supply voltage is below a threshold voltage. In some embodiments, the high voltage function comprises a function associated with providing a supply voltage to the pair of polymorphic gates, wherein the supply voltage is above a threshold voltage. In some embodiments, the pair of polymorphic gates comprises a pair of two bistable feedback gates. In some embodiments, the polymorphic latch further comprises a polymorphic clock buffer/constant-off gate that is coupled to a clock input that is received by the pair of AND logic gates. In some embodiments, the polymorphic clock buffer/constant-off gate is configured to generate logic zero based on a supply voltage that is provided to the pair of polymorphic gates, wherein the supply voltage is below a threshold voltage.

According to some embodiments, a polymorphic register comprises a first polymorphic latch comprising a first data input and a first data output; a second polymorphic latch comprising a second data input and a second data output, wherein the first data output is coupled to the second data input; wherein the first polymorphic latch or the second polymorphic latch comprises a low voltage function and a high voltage function.

In some embodiments, (i) the low voltage function comprises a first logic gate functionality; (ii) the high voltage function comprises a second logic gate functionality, and (iii) the first logic gate functionality is different from the second logic gate functionality. In some embodiments, the low voltage function is associated with providing a supply voltage to the pair of polymorphic gates, wherein the supply voltage is below a threshold voltage. In some embodiments, the high voltage function is associated with providing a supply voltage to the pair of polymorphic gates, wherein the supply voltage is above a threshold voltage. In some embodiments, the first polymorphic latch or the second polymorphic latch comprises a pair of polymorphic gates. In some embodiments, the first polymorphic latch or the second polymorphic latch comprises at least one lookup table.

According to some embodiments, a polymorphic latch comprises at least one lookup table that is configured with a state table, wherein the state table is associated with a D-latch that comprises: (i) a pair of polymorphic gates that is configured as two bistable feedback gates, (ii) an inverter, and (iii) a pair of AND logic gates, wherein: (a) an AND logic gate of the pair of AND logic gates comprises a clock signal input and (1) a data input or (2) an inverted data input, (b) the inverted data input is provided by the inverter, (c) an AND logic gate output of the pair of the AND logic gates is coupled to a respectively corresponding polymorphic gate input of a polymorphic gate of the pair of polymorphic gates, and (d) the D-latch is configured to generate a D-latch output based on a polymorphic gate output of the polymorphic gate.

In some embodiments, the at least one lookup table is configured to receive a polymorphic control signal that is associated with a mode of operation. In some embodiments, the polymorphic control signal is (i) used to trigger a forbidden state and (ii) generated based on a voltage sensor or a temperature sensor. In some embodiments, the at least one lookup table is coupled to a sensor that is configured to provide the polymorphic control signal. In some embodiments, the D-latch output is provided to a feedback input of the polymorphic gate.

### BRIEF DESCRIPTION OF THE DRAWINGS

Embodiments incorporating teachings of the present disclosure are shown and described with respect to the figures presented herein.

FIG. 1 depicts a schematic of an example polymorphic gate in accordance with some embodiments of the present disclosure.

FIG. 2 depicts a schematic of an NCL-based polymorphic NOR/NAND gate according to some embodiments of the present disclosure.

FIG. 3A depicts an example NOR-based D-latch in accordance with some embodiments of the present disclosure.

FIG. 3B depicts an example NAND-based D-latch in accordance with some embodiments of the present disclosure.

FIG. 4A and FIG. 4B depict simulation waveforms of polymorphic NOR/NAND gate behaviors in accordance with some embodiments of the present disclosure.

FIG. 5A and FIG. 5B depict simulation waveforms for a self-destructive polymorphic latch in accordance with some embodiments of the present disclosure.

FIG. 6 depicts a schematic of a GA-based polymorphic NAND/NOR gate according to some embodiments of the present disclosure.

FIG. 7 depicts a schematic of a polymorphic clock buffer/constant-off gate in accordance with some embodiments of the present disclosure.

FIG. 8 depicts simulation waveforms of a polymorphic clock buffer/constant-off gate in accordance with some embodiments of the present disclosure.

FIG. 9 depicts a plot of various gating transistor sizes along with respective polymorphic threshold voltages in accordance with some embodiments of the present disclosure.

FIG. 10 depicts a schematic of an example polymorphic register in accordance with some embodiments of the present disclosure.

FIG. 11 depicts a schematic of a 2-LUT polymorphic latch in accordance with some embodiments of the present disclosure.

FIG. 12 depicts a schematic of a 1-LUT polymorphic latch in accordance with some embodiments of the present disclosure.

### DETAILED DESCRIPTION

Various embodiments of the present disclosure now will be described more fully hereinafter with reference to the accompanying drawings, in which some, but not all embodiments of the disclosure are shown. Indeed, the disclosure may be embodied in many different forms and should not be construed as limited to the embodiments set forth herein. Rather, these embodiments are provided so that this disclosure will satisfy applicable legal requirements. The term “or” is used herein in both the alternative and conjunctive sense, unless otherwise indicated. The terms “illustrative,” “example,” and “exemplary” are used to be examples with no indication of quality level. Like numbers refer to like elements throughout.

### General Overview and Example Technical Improvements

Ensuring data privacy where data is transferred into volatile memory storage may pose a significant challenge as an attacker may be provided with an opportunity to launch passive side-channel attacks that leverage unintentional emissions from caches, latches, flip-flops, and/or registers. Active physical attacks such as optical probing and fault injection, may pose increased threats as attacker may purposefully manipulate the environment, especially the supply voltage. For example, in case of a thermal laser stimulation (TLS) attack, a preliminary step may comprise lowering the supply voltage to a brownout level such that circuit-based countermeasures are disabled beforehand. Such successful attacks have been demonstrated where encryption keys stored in field-programmable gate array (FPGA) memory is revealed using TLS. Such attacks may be equally applicable to application-specific integrated circuits (ASICs). In addition to lowering supply voltage, attackers may also modulate supply voltage at a known frequency and freeze volatile memory contents at a specific time by freezing the system clock (referred to as laser logic state imaging (LLSI)), which may an attacker with an unlimited number of probes to read out values at any point and time of interest. Accordingly, active physical attacks with voltage tampering pose a significant threat to the security of sensitive information stored on-chip memories.

Existing countermeasures are unreliable in protecting against the aforementioned physical attacks. For example, countermeasures, such as LED-based backside thinning detection and backside tamper detection, may detect physical attacks that utilize chip backside manipulation but fail to address voltage glitch attacks. Another existing countermeasure comprises using ring oscillators (ROs) to measure frequency mismatch for detecting environmental disturbances. A network of ring oscillators from a physical unclonable function may be monitored for a change in ring oscillator frequency caused by laser-based probing attempts. However, using ring oscillators comes with high area and power overhead and suffers from false positives due to voltage and temperature variations.

Other circuit-based detectors, such as clock freeze and voltage modulation detectors, on-chip monitors (OCMs), and local electromagnetic (LEMA) detectors, add significant area and power overhead, as well as require separate response mechanisms, such as self-destruction of memory, which is invasive, or memory-zeroization, which is slow and allows attackers time to steal sensitive information. Clock freeze and voltage modulation sensors comprising complementary metal-oxide-semiconductor (CMOS)-compatible analog circuits may be used detect conditions of an LLSI attack. However, such sensors are costly in terms of circuit area. Additionally, clock freeze and voltage modulation sensors are separate from volatile memory elements, and as such, introduces the possibility for an attacker to isolate and disable the sensors, while keeping the volatile memory elements intact and available for exploitation. In addition, detectors may be disabled by lowering supply voltage and even in the presence of detectors, successful glitch attack may be implemented.

Nanopyramid structures may be used to interfere with optical elements of laser-based attacks by scattering an incident laser such that an isolated transistor is unable to be accurately attacked (e.g., lower attack accuracy and less reliable data). Nanopyramid structures may be incorporated during metal 1 layer fabrication but can result in lower device reliability due to higher metal complexity and susceptibility to electromigration.

As described above, there are many technical challenges and difficulties associated with detecting active physical attacks and triggering the destruction of sensitive information stored in volatile memory. Various example embodiments of the present disclosure overcome such technical challenges and difficulties.

Storage elements, specifically latches and registers, may be designed to change their behavior with supply voltage manipulation to automatically destroy their stored data in response—an integrated sense and response countermeasure. The ability of an electronic circuit to change its behavior under different environmental conditions may be referred to as polymorphism and such circuits may be referred to polymorphic circuits.

In accordance with various embodiments of the present disclosure, a self-destructive polymorphic latch for integrating voltage tampering-based attack detection and response functionality into a circuit is disclosed. In some embodiments, the self-destructive polymorphic latch may comprise voltage-controlled polymorphic NOR and/or NAND gates and a polymorphic buffer/always-off gate. In some embodiments, the self-destructive polymorphic latch may operate normally when supply voltage is within an integrated circuit's (IC's) specification and erase the latch's data when the supply voltage is below a specific threshold. In some embodiments, the threshold is calibratable by changing the sizes of one or more transistors. The self-destructive polymorphic latch may be used to cater to different applications and attack conditions. Furthermore, given that the disclosed self-destructive polymorphic latch may only destroy data when its local supply voltage is affected, the self-destruction feature may work equally well against non-invasive (less precise) and semi-invasive (more precise) voltage-manipulation attacks. In some embodiments, the self-destructive polymorphic latch may be extended to self-destructive polymorphic registers.

According to various embodiments of the present disclosure, a volatile memory comprises one or more self-destructive polymorphic latches that are configured to protect sensitive data stored by the volatile memory from physical attacks, such as active side-channel attacks, which are associated with supply voltage manipulation. As such, a self-destructive polymorphic latch may respond to various kinds of attacks that involve voltage manipulation. In some embodiments, a self-destructive polymorphic latch is configured to determine supply voltage interference representative of one or more attacks and react by entering a forbidden data state that causes erasure of data stored by the self-destructive polymorphic latch. For example, a self-destructive polymorphic latch may obfuscate sensitive bits by entering a forbidden data state when an attack's environmental conditions (e.g., voltage manipulation) are fulfilled.

In some embodiments, a self-destructive polymorphic latch comprises a plurality of dual-function asynchronous polymorphic logic gates. The dual-function asynchronous polymorphic logic gates may comprise functionalities (e.g., for causing a self-destructive behavior) that are controlled by a supply voltage. In some embodiments, a dual-function asynchronous polymorphic logic gate's function changes between NOR and NAND based on a threshold supply voltage. In some embodiments, the threshold supply voltage is varied based on transistor sizes. In some embodiments, the threshold supply voltage is varied to match different attack scenarios. In some embodiments, the self-destructive polymorphic latch is configured to instantaneously and locally zeroize data upon attacks.

Accordingly, the disclosed self-destructive polymorphic latch improves upon existing voltage tempering-based attack countermeasure methods by integrating sense and response (zeroization) into a volatile memory element itself, thereby obviating the possibility for an attacker to disable the countermeasure. Additionally, a self-destructive polymorphic latch according to various embodiments of the present disclosure is CMOS-compatible, has minimal power, performance, or area overhead, and does not sacrifice device reliability. In some embodiments, a self-destructive polymorphic latch is optimized by transistor sizing to reduce area overhead and by the addition of a discharge path to destroy data more quickly. In some embodiments, a polymorphic register is constructed from master and slave polymorphic latches. The present application also discloses null convention logic (NCL)-based and genetic algorithm (GA)-based methods of developing polymorphic circuits and/or circuit elements.

### Example Active Physical Attacks

Active physical attacks require physical access to a device under attack and may comprise active manipulation of an environment or parameters, such as system clock, supply voltage, temperature, etc. Examples of active physical attacks comprise TLS, LLSI, and voltage fault injection (VFI). Depending on the nature of an attack, additional steps may also be taken by an attacker. In the case of laser-based attacks, such as TLS and LLSI, an attacker may also freeze a system clock along with supply voltage manipulation. In the case of a VFI attack, an attacker may inject an under-voltage for a short amount of time (e.g., a few hundred nanoseconds) at an appropriate moment, such that the injected fault corrupts system output that may be compared with golden output to determine sensitive information. In the aforementioned attacks, the common attack vector is manipulation of supply voltage in order to disable conventional detection countermeasures.

A TLS attack may be based on the translation of heat to current in a transistor. For example, a transistor may be heated by directing a laser at the transistor thereby changing its resistance. An attacker may scan a region of interest with a laser (e.g., with wavelength of approximately 1300 nm) which causes local heating and generates current at the drain of ‘ON’ transistors. If the transistor is carrying a short-circuit current (e.g., is in on-state), then the current will change due to the change in temperature. A sense amplifier at an output terminal may be used to detect variation in current. By measuring the current using a sense amplifier at each location and performing current variation analysis on each transistor in a volatile memory structure, such as SRAM, an attacker may estimate bias states of each individual transistor and determine data (e.g., bit-by-bit readout of the memory state) stored in volatile memory elements. Performing TLS may require the clock to be frozen to preserve data in the volatile memory cells and prevent sequential elements (e.g., latches and registers) from changing state. TLS may comprise lowering of supply voltage to cause a chip to enter a “brownout” state such that CPU-based defense measures are disabled while keeping the supply voltage high enough for data in volatile memory elements to be retained

$$( e . g . , \frac{{V}_{DD}}{2} ) .$$

LLSI comprises a fault analysis technique that may be used to detect faults by analyzing static signals of nodes or registers in a chip. However, LLSI may also be used by attackers to obtain static signals of any node or register to extract sensitive assets. In LLSI, a laser with a near infrared wavelength may be used to scan an ROI of a chip. Incident light from the laser may be partially absorbed and partially reflected by the ROI. At the near infrared wavelength, the laser energy may be above silicon band-gap and transparent to bulk silicon. The intensity of the reflected light may be used to distinguish between transistors in “ON” or “OFF” states. Reflected light carrying sensitive information may be fed to a detector comprising a spectrum analyzer that is configured at a known modulation frequency. A 2D image may be generated by the spectrum analyzer, which provides data carried by any node, gate, or memory element in the chip thereby divulging sensitive information. Similar to TLS, performing LLSI may comprise freezing the clock at an instance where sensitive information is available, keeping sequential elements from changing state. However, unlike TLS, supply voltage may be modulated at a known frequency such that the chip is still operational where the amplitude of modulation is large enough to obtain clear distinguishing signatures of ‘ON’ and ‘OFF’ transistors and none of the gates or registers lose their original states.

A VFI attack may comprise using a transistor-based setup or an arbitrary waveform generator to trigger voltage glitches on chips. A voltage glitch may comprise a sudden temporary voltage drop from logic “1” to logic “0.” A software-based framework may also be designed to inject faults by triggering voltage glitches at appropriate times such that results of the injected faults may be used to extract assets by analyzing circuit behavior under fault.

### Example Polymorphic Gates

According to various embodiments of the present disclosure, a self-destructive polymorphic latch comprises one or more polymorphic gates. A polymorphic gate may comprise a logic circuit that changes functionality in response to factors such as voltage, temperature, and/or light.

In some embodiments, a genetic algorithm (GA) is used to design and/or optimize a design of a polymorphic gate by iteratively improving a set of candidate circuit variables. Using a GA to design a polymorphic gate may comprise selecting a specific design of which transistor sizes are evolved as well as which transistor to evolve. For example, a GA may be used to optimize transistors of polymorphic gates in specific circuit designs to achieve a desired self-destructive behavior while minimizing overall circuit size. In some embodiments, a GA is used for sizing transistors such that gate output behavior changes with a design variable. In some embodiments, before executing a GA, parameters comprising population size, tournament size, mutation rate, and/or range of transistor widths and lengths are configured. Table 1 provides example values of the aforementioned parameters that may be used in a GA for optimizing a design of a polymorphic gate.

TABLE 1

| Population | Tournament | Mutation | Width Range | Length Range |
|---|---|---|---|---|
| Size | Size | Rate | (nm) | (nm) |
| 300 | 4 | 0.3 | 120-10000 | 45-10000 |

The following provides example operations of a GA process for designing a polymorphic gate in accordance with some embodiments of the present disclosure.

Initial Population Generation: In some embodiments, an initial population of polymorphic gate circuits is generated with transistor sizes that are stochastically determined within predefined ranges for widths and lengths. An example Algorithm 1 for performing initial population generation is disclosed by the following:

Algorithm 1 Initial Population

for i ← 0; i < populationSize; i + + do
widths ← randomSizes(widthRange)
lengths ← randomSizes(lengthRange)
population[i] ← [widths, lengths]
end for

Fitness Evaluation: In some embodiments, each polymorphic gate circuit in the population is evaluated using a fitness function that measures how well transistor sizes (e.g., width and length) of the polymorphic gate circuit meets one or more design requirements.

Selection: In some embodiments, a tournament selection function is used to choose best circuit candidates for a next generation. Tournament selection may comprise sampling fitness values, selecting best circuits based on the fitness values sampled, and designating the best circuits as parents. An example Algorithm 2 for performing tournament selection is disclosed by the following:

Algorithm 2 Tournament Selection

tournament1 ← randomSample(fitnessV alues)
bestCandidate1 ← maxFitness(tournament1)
tournament2 ← randomSample(fitnessV alues)
bestCandidate2 ← maxFitness(tournament2)

Crossover and Mutation: In some embodiments, a crossover function is used to generate a new population by combining the transistor sizes (e.g., width and length) of selected parents. A mutation function may be used to introduce random changes in the transistor sizes to maintain genetic diversity and avoid local minima. An example Algorithm 3 for performing crossover and mutation is disclosed by the following:

Algorithm 3 Crossover

```
for j ← 0; j < numberOf Transistors; j + + do
widths[j] ← random(candidate1[j], candidate2[j])
lengths[j] ← random(candidate1[j], candidate2[j])
if random(0, 1) ≤ mutationRate then
    widths[j] ← random(minWidth, maxWidth)
    lengths[j] ← random(minLength, maxLength)
  end if
end for
child ← [widths, lengths]
```

In some embodiments, a GA may iteratively perform the above-described fitness evaluation, tournament selection, and crossover and mutation operations until a stopping criterion is met. An example Algorithm 4 for performing a GA to determine a best polymorphic gate circuit design is disclosed by the following:

Algorithm 4 Genetic Algorithm

```
population ← firstPopulation( )
while bestFitness > 0.1 do
  for i ← 0; i < populationSize; i + + do
    fitness[i] ← getFitness(population[i])
  end for
  bestFitness ← max(fitness)
  for i ← 0; i < populationSize; i + + do bestCandidates ←
  tournamentSelection(fitness)
    child ← crossoverFunction(bestCandidates) population.append(child)
  end for
end while
```

The Algorithm 4 stops when the best circuit candidate achieves a fitness score below 0.1.

In some embodiments, a polymorphic gate is designed based on multi-threshold NCL. NCL may comprise a methodology for designing asynchronous circuitry that uses dual rail logic. Accordingly, designing a polymorphic gate based on NCL may comprise using a threshold voltage drop of a diode-connected NMOS transistor to create polymorphism with supply voltage change.

In some embodiments, designing a polymorphic gate based on NCL comprises creating a polymorphic gate based on a selection of two logic functions—a low voltage function and a high voltage function. In some embodiments, the low voltage function may comprise a function of a polymorphic gate during which a supply voltage V_{DD} at the polymorphic gate is below a given brownout threshold voltage V_{B}. Conversely, the high voltage function may comprise a function of a polymorphic gate during which the supply voltage V_{DD} at the polymorphic gate is above the brownout threshold voltage V_{B}. In some embodiments, the low voltage function may comprise a Boolean subset of the high voltage function. That is, the high voltage function may comprise a less specific Boolean equation and the low voltage function may comprise a more specific Boolean equation. For example, a NAND operation may be considered as a Boolean subset of a NOR operation and thus, selected as a low voltage function because the NAND operation has similar, but stricter conditions to output a logic “0” than the NOR operation.

The two logic functions (e.g., the low voltage function and the high voltage function) may be used to generate a logic gate comprising a pull-down network (PDN) that is associated with the high voltage function) that is connected to a pull-up network (PUN) that is associated with the low voltage function). The PDN may comprise PDN transistors that are sized larger (e.g., five times) than PUN transistors of the PUN. The logic gate may further comprise two gating n-channel metal-oxide-semiconductors (NMOS) transistors. In some embodiments, a first gating NMOS transistor in threshold drop configuration may be configured to drive a gate of a second gating NMOS transistor that gates a connection between the PDN and ground. The two gating NMOS transistors may be sized to select a threshold voltage to cause the logic gate to exhibit polymorphic behavior (e.g., changes from NOR to NAND and vice versa). The logic gate may further comprise an output buffer stage, with sleep transistors, for use with NCL.

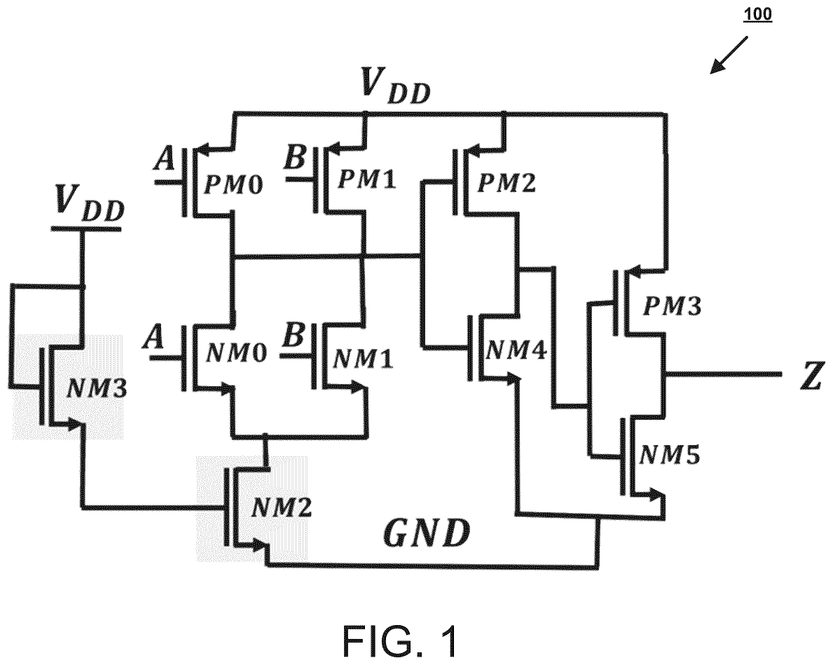

FIG. 1 depicts a schematic of an example polymorphic gate 100 in accordance with some embodiments of the present disclosure. The polymorphic gate 100 comprises (i) a pullup network comprising a NAND gate including PM0, PM1, and PM2 transistors and (ii) a pulldown network comprising a NOR gate including NM0, NM1, and NM4 transistors. In the depicted example, NAND is considered to be a Boolean subset of NOR, as it outputs a logic “0” under stricter logical conditions than NOR, thus NAND may comprise a low voltage function and NOR may comprise a high voltage function. The polymorphic gate 100 further comprises threshold gating NMOS transistors NM2 and NM3 (highlighted), where NM3 is connected in threshold-drop configuration and provides gate voltage to NM2. At high voltages, the gating NMOS transistors connect the dominant PDN to ground, allowing the high voltage function to dominate. At low voltages, the gating transistors are turned off, and the PDN is disconnected from ground. The PUN is then able to drive the output functionality. The polymorphic gate 100 further comprises an output buffer comprising PM3 and NM5 transistors.

As disclosed herewith, two methodologies of polymorphic latch and register design are provided. In some embodiments, NCL is used to design a polymorphic NOR/NAND gate for constructing a polymorphic latch and/or register therefrom. In some embodiments, a GA is used to optimize transistor sizing in an NCL-based design. In some embodiments, a GA is used to design and optimize a polymorphic NOR/NAND gate for constructing a polymorphic latch and/or register.

### Example NCL-Based Polymorphic Latch

### Example NCL-Based Polymorphic NOR/NAND Gate

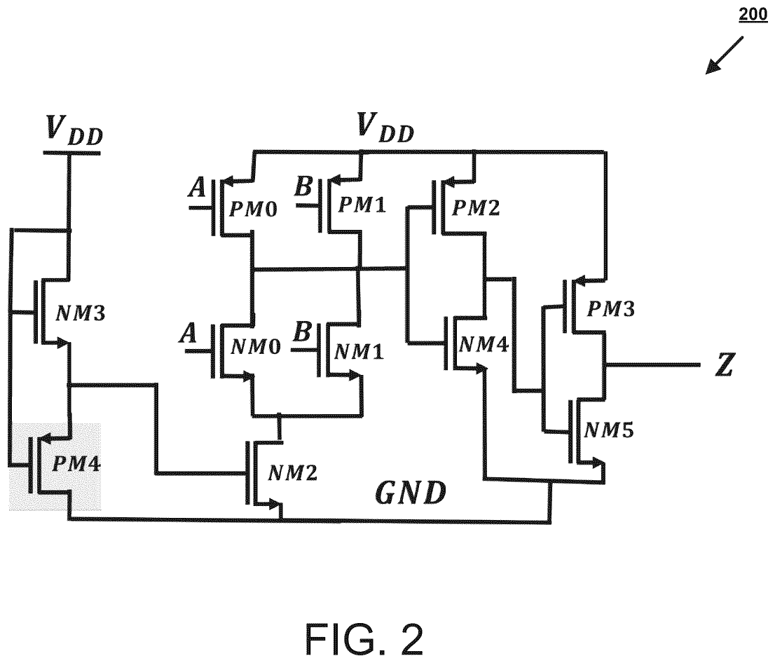

FIG. 2 depicts a schematic of an NCL-based polymorphic NOR/NAND gate 200 according to some embodiments of the present disclosure. The NCL-based polymorphic NOR/NAND gate 200 comprises a PUN and a PDN. The PUN comprises a 2-input NAND gate that comprises two p-channel metal-oxide-semiconductor (PMOS) transistors PM0 and PM1 in parallel. The PDN comprises a 2-input NOR gate that comprises two NMOS transistors NM0 and NM1 in parallel. The depicted NCL-based polymorphic NOR/NAND gate 200 may be an optimized polymorphic NOR/NAND gate where twofold optimization has been achieved. In some embodiments, a GA is applied to resize the transistors of an original polymorphic NOR/NAND gate design, providing an optimal threshold voltage and minimized area. Example transistor sizes of an original design and an optimized design are provided in Table 2.

TABLE 2

| | Original | Optimized |
|---|---|---|
| Transistors | Width (nm) | Width (nm) |
| NM0, NM1 | 600 | 600 |
| NM2, NM3 | 1800 | 810 |
| NM4, NM5 | 120 | 120 |
| PM0, PM1, PM2, PM3 | 120 | 120 |
| PM4 | N/A | 2100 |

Table 2 depicts example transistor sizes of the NCL-based polymorphic NOR/NAND gate 200. The NMOS transistors NM0, NM1 of the PDN may be sized to be five times larger (600 nm) than the PMOS transistors PM0, PM1 of the PUN (120 nm) such that high voltage functionality associated with the PDN dominates when all transistors are in an “on” state.

An additional PMOS transistor PM4 (highlighted in FIG. 2) is added which is connected to the threshold drop-configured NMOS transistor, improving the response time of the latch to an attack. A genetic algorithm may be used to optimize the width of NM2 and NM3 to 810 nm in a technology node where the length of all transistors is set at 45 nm. The width of additional PMOS transistor PM4 is 2100 nm to improve response time by providing a discharge path for gate voltage of NM2 when NM3 is ‘OFF’.)

Polymorphism is established through two NMOS transistors NM2 and NM3 where NM3 is connected in a threshold-drop configuration and providing gate voltage to NM2. When the supply voltage is lower than a threshold V_{B} (e.g., brownout voltage), the gate voltage of NM2 is not high enough to turn it on and quickly discharges through PM4. Thus, the PDN is disconnected, and the PUN ensures NAND behavior. However, when the supply voltage is above the threshold V_{B}, both NM2 and NM3 are fully on and NOR functionality is ensured through PDN. To ensure this, pull-down transistors are sized about five times compared to pull-up transistors. The truth table of the operation of NCL-based polymorphic NOR/NAND gate 200 is provided in Table 3.

TABLE 3

| | | Z(NAND) | Z(NOR) |
|---|---|---|---|
| A | B | V_{DD} < V_{B} | V_{DD} > V_{B} |
| 0 | 0 | 1 | 1 |
| 0 | 1 | 1 | 0 |
| 1 | 0 | 1 | 0 |
| 1 | 1 | 0 | 0 |

The NCL-based polymorphic NOR/NAND gate 200 further comprises an output buffer that is connected at the output located between the PUN and the PDN. The output buffer comprises two inverters comprising PM2, NM4 and PM3, NM5 that are coupled back-to-back. Two additional NMOS transistors, NM2 and NM3, may be used to gate the PDN and change the behavior of NCL-based polymorphic NOR/NAND gate 200 with supply voltage variation. NMOS transistor NM3 is connected in threshold drop configuration with its gate and drain connected to supply voltage V_{DD}. The source of NMOS transistor NM3 may drive the gate of NMOS transistor NM2 to control the PDN's connection to ground. NMOS transistor NM3 may experience a voltage drop across its channel up to its threshold voltage. As such, when V_{DD} is near the threshold voltage, a signal driving the gate of NMOS transistor NM2 may become degraded and unable to turn on NMOS transistor NM2, causing the PDN to be disconnected and NAND functionality to dominate. However, when V_{DD} is higher than the threshold voltage, NMOS transistor NM2 is turned on and connects the PDN to ground, causing NOR functionality to dominate.

### Example NCL-Based Polymorphic Latch Design

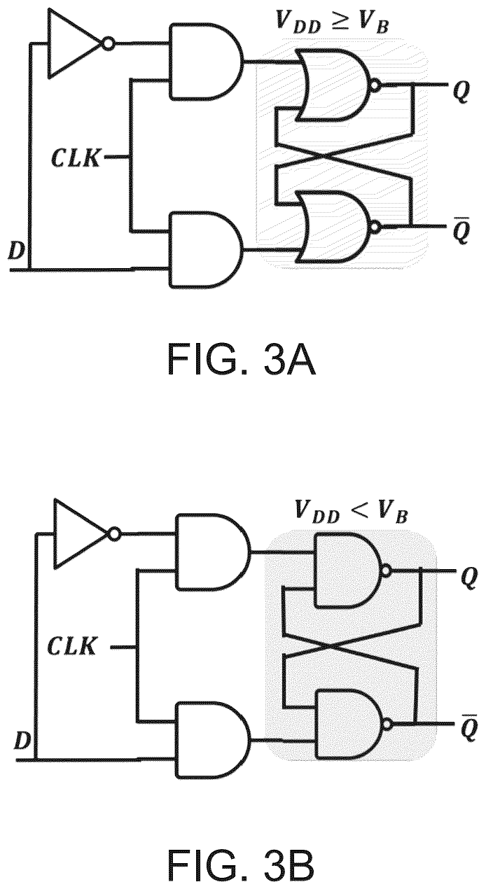

In some embodiments, an NCL-based polymorphic latch comprises a pair of NCL-based polymorphic NOR/NAND gates (e.g., NCL-based polymorphic NOR/NAND gate 200) that are configured based on circuits depicted in FIG. 3A and FIG. 3B (e.g., a D-latch). In some embodiments, an NCL-based polymorphic latch comprises (i) a pair of NCL-based polymorphic NOR/NAND gates that are configured as two bistable feedback gates, (ii) a pair of AND logic gates, and (iii) an inverter. Each of the AND logic gates is configured to receive a clock input and either a data input or an inverted data input. An inverter is coupled to an input of one of the AND logic gates to provide the inverted data input. Each output of the pair of AND logic gates is coupled to a respectively corresponding input of each NCL-based polymorphic NOR/NAND gate.

In some embodiments, a non-volatile memory comprising one or more NCL-based polymorphic latches is configured to protect sensitive data from physical attacks by instantaneously erasing data based on the NCL-based polymorphic latch's voltage condition. The one or more NCL-based polymorphic latches may comprise one or more polymorphic gates. In some embodiments, the polymorphic nature of the NCL-based polymorphic latch may result from the one or more polymorphic gates comprising behavior derived from a latch constructed with NOR gates versus that of a latch constructed with NAND gates. For example, an NCL-based polymorphic latch comprising NCL-based polymorphic NOR/NAND gates may operate (normally) as a NOR-based D-latch when supply voltage V_{DD} is greater than or equal to brownout voltage V_{B}, as depicted in FIG. 3A and Table 4. During NOR operation, an NCL-based polymorphic latch may comprise the ability to hold data when the clock signal (CLK) is low (0). On the other hand, when the clock is high (1), it will set (reset) Q if D=1 (D=0).

TABLE 4

| CLK | D | Q | Q̅ |
|---|---|---|---|
| 0 | X | Q | Q̅ |
| 1 | 0 | 0 | 1 |
| 1 | 1 | 1 | 0 |

In some embodiments, when a supply voltage V_{DD} drops to a brownout voltage V_{B}, such as during a TLS attack, the functionality of the polymorphic NOR/NAND gates may change from NOR to NAND. That is, a NCL-based polymorphic latch that operated as a NOR-based D-latch under normal operating conditions (e.g., supply voltage V_{DD} is above the brownout voltage V_{B}) may operate as a NAND-based D-latch when supply voltage V_{DD} is less than V_{B}, as depicted in FIG. 3B and Table 5.

TABLE 5

| CLK | D | Q | Q̅ |
|---|---|---|---|
| 0 | X | 1 | 1 |
| 1 | 0 | 0 | 1 |
| 1 | 1 | 1 | 0 |

A switch of the polymorphic NOR/NAND gates to NAND operation may occur when the system clock, CLK, is low. During NAND operation, the NCL-based polymorphic latch may enter a forbidden state when CLK is low (0), as depicted in the first column of Table 5. That is, regardless of D, the outputs Q and Q̅ both output a logic 1, due to the NAND gates both having a low input when CLK=0. This state, with Q and Q̅ equal, does not represent valid data and effectively destroys any previous state data contained in the latch. Thus, the change in gate functionality causes the NCL-based polymorphic latch to enter a forbidden state, which may cause meta-stability in the polymorphic latch and settling to a random value when the supply voltage returns to normal operating condition, effectively “self-destructing” its data. Accordingly, when the conditions of a TLS attack are fulfilled, both the Q and Q̅ outputs are raised to V_{DD}, which causes destruction of any previously stored data in the NCL-based polymorphic latch and effectively prevents sensitive data from being read out.

As such, by constructing a latch (e.g., a NCL-based polymorphic latch) with one or more polymorphic NOR/NAND gates, the latch can function normally for a voltage above V_{B} where the one or more polymorphic gates operate as NOR gates, but enter a forbidden state when the clock is stopped and the supply voltage is below V_{B} and the one or more polymorphic gates operate as NAND gates. Since lower voltage or voltage modulation are prerequisites of physical attacks, a latch comprising one or more polymorphic NOR/NAND gates can effectively destroy data when a supply voltage drops below a configurable threshold based on V_{B}. An NCL-based polymorphic latch as disclosed herewith is equally applicable to registers that comprise two latches in series and may be used to construct a polymorphic self-destructive register by using two NCL-based polymorphic latches.

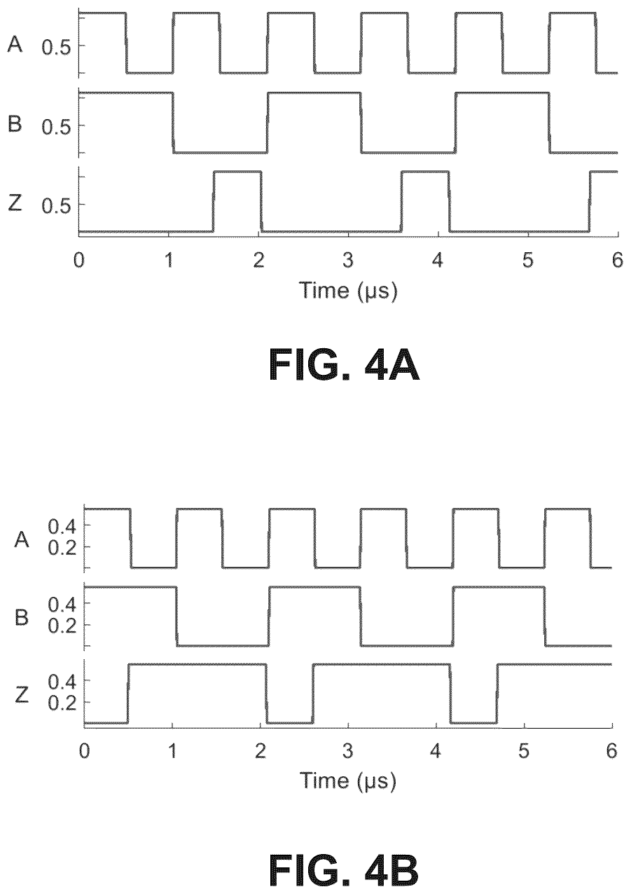

FIG. 4A and FIG. 4B depict simulation waveforms of polymorphic NOR/NAND gate behaviors in accordance with some embodiments of the present disclosure. The waveforms depicted in FIG. 4A are associated with NOR gate functionality (e.g., Z (NOR) from Table 3) of a polymorphic NOR/NAND gate operating with a supply voltage of 1.1V (e.g., above a threshold voltage). FIG. 4A further depicts the output, Z, is only high if inputs A and B are both low. Otherwise, Z is low.

FIG. 4B depicts waveforms that are associated with NAND gate function (e.g., Z (NAND) from Table 3) of a polymorphic NOR/NAND gate operating with a supply voltage of 0.55V (e.g., below a threshold voltage). As further depicted by FIG. 4B, the gate output Z is only low if inputs A and B are both low. Otherwise, the gate output Z is high.

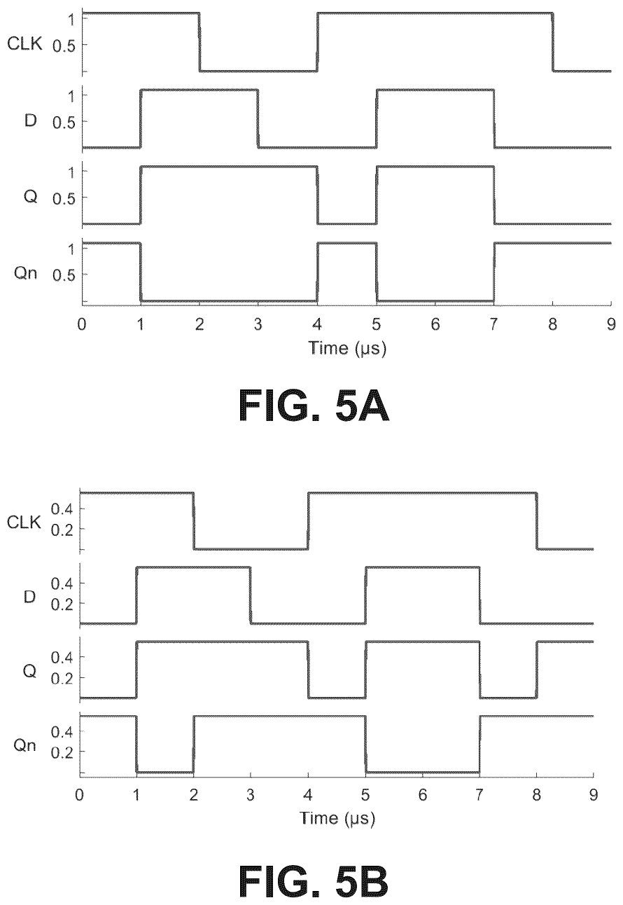

FIG. 5A and FIG. 5B depict simulation waveforms for an NCL-based polymorphic latch operating under supply voltages of 1.1V and 0.55V, respectively. At 1.1V, the NCL-based polymorphic latch operates normally. As depicted in FIG. 5A, the data is latched from D to Q when the CLK input is high, and when the CLK is low, the NCL-based polymorphic latch preserves state.

At 0.55V, the NCL-based polymorphic latch exhibits destructive behavior. As depicted in FIG. 5B, when the CLK is low, outputs Q and Q̅ both enter logical high state, which does not represent valid data and causes destruction of the NCL-based polymorphic latch's previous data state.

### Multi-Threshold Null Convention Logic

In some embodiments, an NCL-based polymorphic latch comprises one or more polymorphic gates that are designed using multi-threshold null convention logic (MTNCL). MTNCL may comprise a design methodology utilized in the implementation of asynchronous logic circuits. MTNCL may use dual-rail encoding to represent valid data of “0” and “1” to preserve a principle of quasi-delay-insensitivity provided by traditional NCL, under which a clock is not needed to synchronize data changes in a pipeline. MTNCL may expand upon NCL by including sleep transistors with high threshold voltages. Sleep transistors may force the logic into a low-power sleep state to reduce leakage current and to separate data states. Implementing polymorphic circuits as asynchronous circuits allows for low area overhead and afford simpler timing analysis. However, NCL-based polymorphic latches according to various embodiments of the present disclosure comprise either a synchronous circuit or an asynchronous circuit.

### Example Genetic Algorithm-Based Polymorphic Latch

### Example GA-Based Polymorphic NAND/NOR Gate

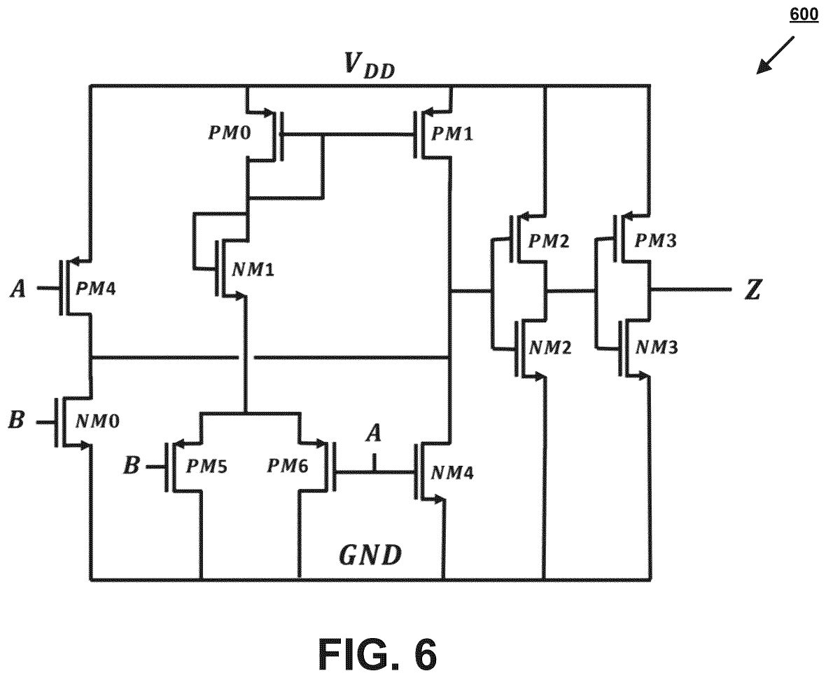

As disclosed herewith, a GA may be used to design a polymorphic gate to obtain a desired polymorphic behavior as well as optimize transistor sizing. FIG. 6 depicts a schematic of a GA-based polymorphic NAND/NOR gate 600 according to some embodiments of the present disclosure. The GA-based polymorphic NAND/NOR gate 600 operates as a NAND gate under normal operating condition and behaves as a NOR gate at lower voltages than a threshold voltage (e.g., brownout voltage).

In some embodiments, when inputs A and B are of the same logic value (either logic high or low), the GA-based polymorphic NAND/NOR gate 600 behaves as an inverter. For example, when both inputs A and B are logic low, NM0 and NM4 switches off and output Z is logic high through PM4 and PM1. When both inputs A and B are logic high, NM0 and NM4 switches on and drive the gate output Z to logic low. Such inverter behavior exists for both NAND and NOR operations of the GA-based polymorphic NAND/NOR gate 600. Polymorphic behavior occurs when inputs have different logic as shown in the Table 6.

TABLE 6

| | | Z(NOR) | Z(NAND) |
|---|---|---|---|
| A | B | V_{DD} < V_{B} | V_{DD} > V_{B} |
| 0 | 0 | 1 | 1 |
| 0 | 1 | 0 | 1 |
| 1 | 0 | 0 | 1 |
| 1 | 1 | 0 | 0 |

In some embodiments, when input A is logic low and input B is high, both NM0 and PM1 switch on. Depending on the supply voltage, the output Z either settles at logic low through NM0 or logic high through PM1. If the supply voltage is above a certain threshold V_{B} (assuming suitable sizes for the transistors), PM1 overtakes, and output Z settles at logic high.

In some embodiments, when input A is logic high and input B is logic low, both NM4 and PM1 switch on and PM1 overtakes if the supply voltage is above the threshold V_{B} and drives the output Z to logic high. If supply voltage is below the threshold V_{B}, output Z becomes logic low through NM4.

The threshold for polymorphism may depend on transistor sizing specially of transistors PM1 and NM4. Transistor sizing may be optimized using GA. Example transistor size values are provided in Table 7.

TABLE 7

| Transistors | Width (nm) | Length (nm) |
|---|---|---|
| NM0 | 120 | 450 |
| NM1 | 800 | 45 |
| NM2, NM3 | 120 | 45 |
| NM4 | 120 | 6000 |
| PM0 | 120 | 3000 |
| PM1 | 3000 | 145 |
| PM2, PM3, PM4 | 120 | 45 |
| PM5, PM6 | 2900 | 120 |

### Example GA-Based Polymorphic Latch Design

In some embodiments, a GA-based polymorphic NAND/NOR gate may operation as a NAND gate as the normal operating condition instead of a NOR gate for a GA-based polymorphic latch (e.g., opposite of the disclosed NCL-based polymorphic latch). For example, under normal operation when supply voltage V_{DD} is above the threshold V_{B} a GA-based polymorphic NAND/NOR gate in a GA-based polymorphic latch may operate as a NAND gate and the GA-based polymorphic latch latches the data, operating as intended. Under attack conditions when supply voltage V_{DD} falls below the threshold V_{B}, the GA-based polymorphic gate may change its behavior to NOR and the latch enters a forbidden state when the clock is logic low.

### Example Polymorphic Clock Buffer/Constant-Off Gate

As disclosed herewith, a self-destructive polymorphic latch comprising polymorphic NOR/NAND gates may enter a forbidden state and clear stored data when CLK input is “0.” However, during an attack, it is possible for an attacker to freeze the system clock in the “1” state, in which case the latch may still contain previously stored data. To mitigate freezing of the system clock, a self-destructive polymorphic latch may further comprise a polymorphic clock buffer/constant-off gate that is coupled to a clock tree (e.g., clock input of the self-destructive polymorphic latch) to force the system clock to “0” under attack conditions to ensure that the self-destructive polymorphic latch will be able to clear its data.

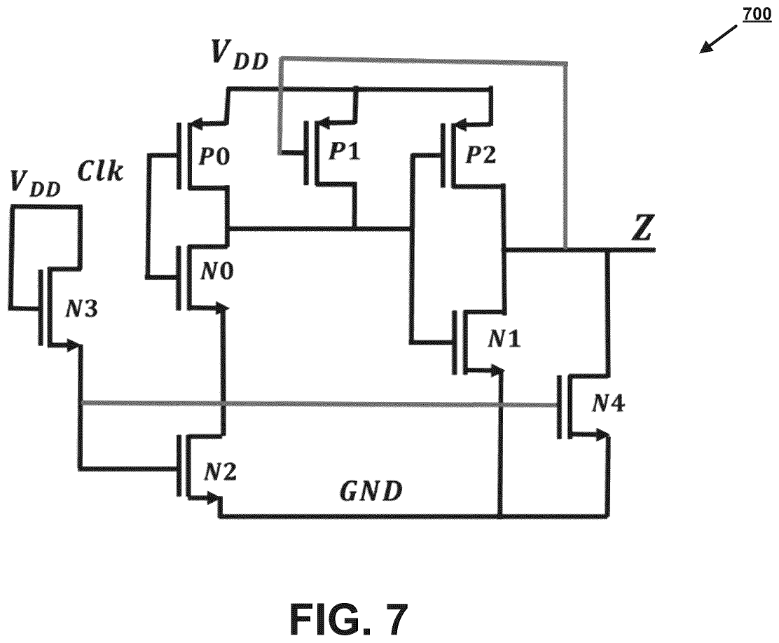

FIG. 7 depicts a schematic of a polymorphic clock buffer/constant-off gate 700 according to some embodiments of the present disclosure. The polymorphic clock buffer/constant-off gate 700 comprises a polymorphic combination of a NOR/XNOR gate followed by an inverter stage. Logical operation of the polymorphic clock buffer/constant-off gate 700 is depicted in Table 8.

TABLE 8

V_{DD}

| CLK | 1.1 V | 0.55 V |
|---|---|---|
| 0 | 0 | 0 |
| 1 | 1 | 0 |

When supply voltage is high, the gate acts as a buffer and passes the value of the clock signal unaltered. However, when supply voltage is low, the gate acts as a constant-off gate, outputting a logic “0” regardless of the actual clock value.

The polymorphic clock buffer/constant-off gate 700 may comprise a NOR high voltage function and a XNOR low voltage function. Accordingly, the polymorphic clock buffer/constant-off gate 700 comprises a PDN that comprises a 1-input NOR gate (N0) and a PUN that comprises an XNOR gate (P0, P1). However, to eliminate the need to invert CLK to drive the gate of P1, a keeper configuration is used where the gate of P1 is connected to the output Z. This ensures that at 0.55V operation, the inverter (P2, N1) is constantly driven by at least one path to V_{DD} and thus the output Z, is constant 0. A weak NMOS transistor N4 is also connected between the output and ground to ensure that the output pulls low as soon as the supply voltage drops. The polymorphic clock buffer/constant-off gate 700 also comprises gating transistors N3 and N2, respectively.

Table 9 provides example transistor sizing for polymorphic clock buffer/constant-off gate 700.

TABLE 9

| Transistors | Width (nm) | Length (nm) |
|---|---|---|
| N0, P2 | 360 | 45 |
| N2, N3 | 1800 | 45 |
| N1, P0, P1 | 120 | 45 |
| N4 | 180 | 45 |

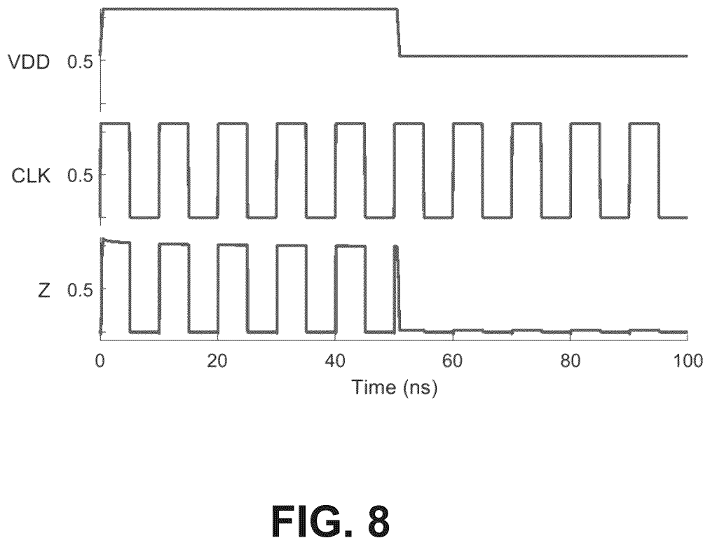

FIG. 8 depicts simulation waveforms of a polymorphic clock buffer/constant-off gate operating during a change in supply voltage from 1.1V to 0.55V. When V_{DD} is 1.1V, the clock buffer passes the value of CLK to Z. When V_{DD} is 0.55V, the polymorphic clock buffer/constant-off gate switches functionality to a constant-off gate and the output remains at logic zero (0).

### Adjusting Self-Destruction Threshold Per Attack

According to various embodiments of the present disclosure, a self-destructive polymorphic latch may provide adaptability to various attack models. As such, it may be desirable for the voltage V_{B} at which polymorphic gates of a self-destructive polymorphic latch changes state to be configurable based on usage in different applications. For example, in a TLS attack, an attacker may set a supply voltage to a reduced voltage close to brownout voltage. However, in the case of a 45 nm technology node with a supply voltage of 1.1V, the brownout voltage may be approximately 550 mV. In another example, an LLSI attack may comprise an attacker modulating a supply voltage at an amplitude of approximately 400 mV peak-to-peak, but as high as 700 mV peak-to-peak without disturbing normal functionality, thus setting a threshold between 900 mV and 1V may be more suitable. In yet another example, a voltage glitch attack may comprise dropping a supply voltage to logic “0” temporarily, for example, a span of about 200 ns. Such a voltage drop is substantial and if response time of an attacked circuit is faster than 200 ns, any threshold voltage may be suitable to detect such glitch.

In some embodiments, the polymorphism of a polymorphic NOR/NAND gate can be controlled by varying the sizing of gating transistors in the PDN, for example, NM2 and NM3 of polymorphic NOR/NAND gate 200. That is, the polymorphic threshold of a polymorphic NOR/NAND gate may be inversely proportional to the size of NM2 and NM3, which are equally sized.

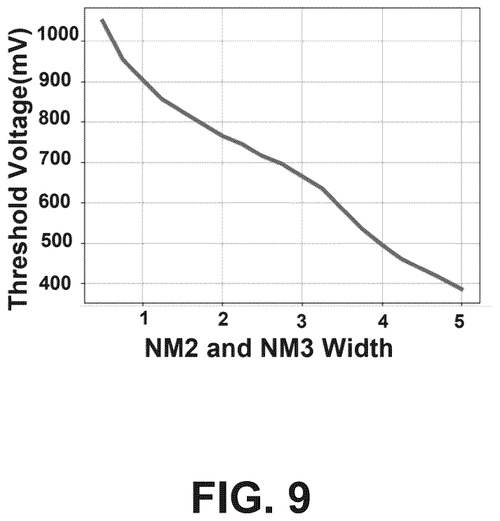

FIG. 9 depicts a plot of various gating transistor sizes (NM2 and NM3) along with respective polymorphic threshold voltages according to some embodiments of the present disclosure. As depicted in FIG. 9, a decrease in polymorphic voltage is approximately linear with an increase in transistor size. Based on FIG. 9, a width of approximately 3.5 μm may be suitable for a TLS attack countermeasure where a width of approximately 0.5 μm may be suitable for an LLSI countermeasure.

### Example Polymorphic Register

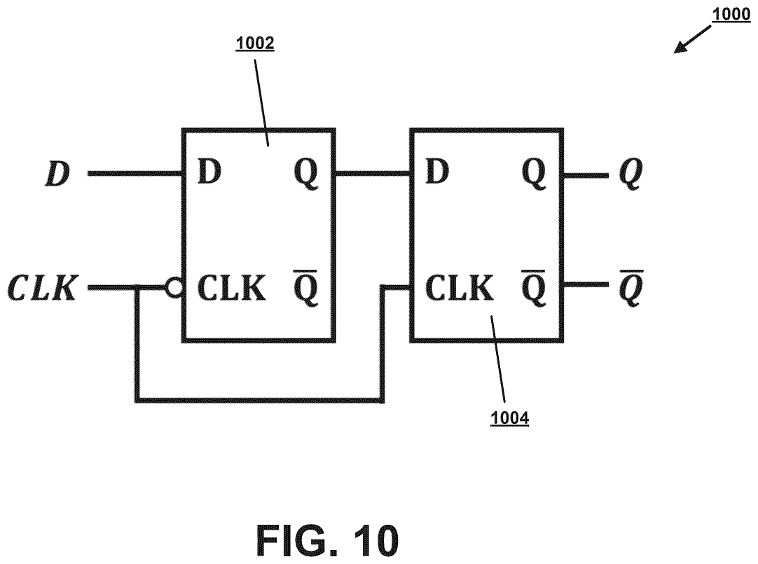

FIG. 10 depicts a schematic of an example polymorphic register 1000 in accordance with some embodiments of the present disclosure. The polymorphic register is designed by connecting two polymorphic latches, 1002 and 1004, back-to-back. That is, the polymorphic latches 1002 and 1004 are connected in series such that the Q output of the polymorphic latch 1002 is coupled to a D input of the polymorphic latch 1004 while the CLK input of both polymorphic latches 1002 and 1004 are coupled to a common CLK signal. As such, the input of polymorphic register 100 may be provided by the D input of the polymorphic latch 1002 and the output of the polymorphic register 1000 may be provided by the Q and/or Q̅ output of the polymorphic latch 1004. In the case of an NCL-based polymorphic register, the latches used may comprise NCL-based latches and in the case of a GA-based polymorphic register, the latches used may comprise GA-based latches.

### Example Implementation of Polymorphism in FPGA

Active physical attacks, such as TLS, LLSI, or VFI, may also be used against FPGAs. As such, the disclose polymorphic latch designs may be utilized for data protection within an FPGA. A lookup table (LUT) approach for implementing polymorphic latches in reconfigurable circuits is disclosed herewith. While the LUTs themselves may not exhibit traditional sense-and-response polymorphic behavior, LUT's may be combined with on-chip sensors to effectively counter physical attacks.

### 2-LUT Polymorphic Latch

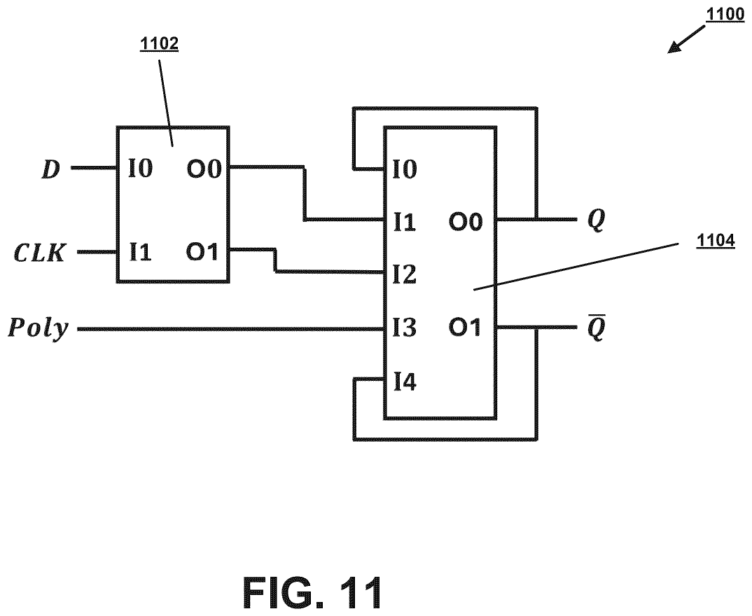

FIG. 11 depicts a schematic of a 2-LUT polymorphic latch 1100 in accordance with some embodiments of the present disclosure. The 2-LUT polymorphic latch 1100 may be implemented within an FPGA. The 2-LUT polymorphic latch 1100 comprises a two-input, two-output LUT 1102 that is coupled to a five-input, two-output LUT 1104. LUT 1102 and LUT 1104 may be programmed with state tables that map, for example, the gates of a D-latch from FIG. 3A or FIG. 3B into LUT 1102 and LUT 1104. For example, LUT 1102 may be configured (e.g., to logically function as) as an inverter and a pair of AND logic gates, wherein (i) each of the pair of AND logic gates is configured to receive a clock signal and either a data input or an inverted data input and (ii) the inverter is coupled to an input of one AND logic gate of the pair of AND logic gates to provide the inverted data input. Accordingly, the I0 and I1 inputs of the LUT 1102 are configured to provide the CLK (clock input) and D (data input) signals as input to the pair of AND logic gates and the O0 and O1 outputs of the LUT 1102 are configured to provide Q and Q̅ outputs from the pair of AND logic gates.

The LUT 1104 may be configured (e.g., logically) as a pair of polymorphic NAND/NOR gates that are configured as two bistable feedback gates. The O0 and O1 outputs of the LUT 1102 are coupled to the I1 and I2 inputs of LUT 1104. As such, the I1 and I2 inputs of the LUT 1104 may comprise inputs that respectively correspond to the pair of polymorphic NAND/NOR gates. A third input, I3, comprises a Poly input, which may control whether the O0 and O1 outputs of the LUT 1104 reflect a specific mode of operation (e.g., normal operation or forbidden state) of the 2-LUT polymorphic latch 1100. In some embodiments, the I3 input is configured to receive a polymorphic control signal, wherein the polymorphic control signal is (i) used to trigger a forbidden state and (ii) generated based on an external trigger source, such as a voltage sensor or a temperature sensor. The O0 and O1 outputs of the LUT 1104 comprise latch signals Q and Q̅, that are representative of a value stored on a memory device comprising the 2-LUT polymorphic latch 1100. The Q and Q̅ outputs are fed back in loop configuration to the I0 and I4 inputs of the LUT 1104.

The delay in the paths between Q/Q̅ and the LUT inputs I0 and I4 controls the state in which the 2-LUT polymorphic latch 1100 returns when the Poly signal is eventually de-asserted (referred to herein as the restoration state of the latch). When the Q feedback path has greater delay than the Q̅ feedback path, the 2-LUT polymorphic latch restores to a 1/0 output state. Conversely, higher delay in the Q̅ feedback path corresponds to a 0/1 restoration state. By adding delays to the feedback paths, control may be provided of what the latch data restores to after the forbidden state is exited.

### 1-LUT Polymorphic Latch

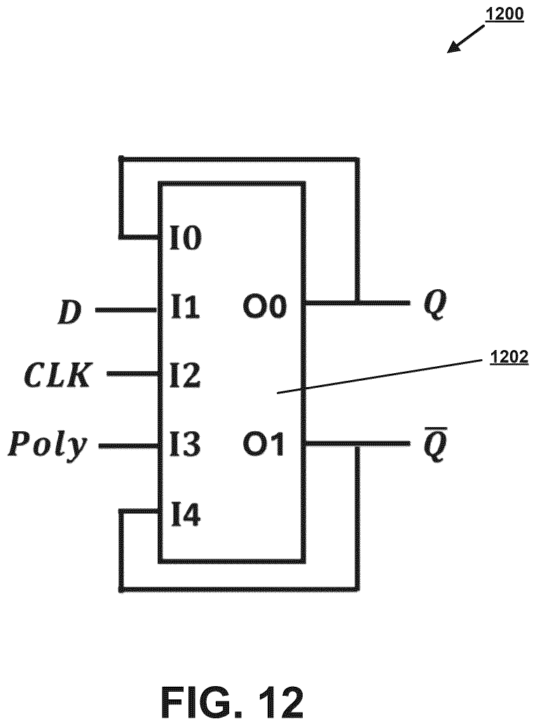

FIG. 12 depicts a schematic of a 1-LUT polymorphic latch 1200 in accordance with some embodiments of the present disclosure. The 1-LUT polymorphic latch 1200 may be implemented in an FPGA. The 1-LUT polymorphic latch 1200 comprises a five-input, two-output LUT 1202 that is programmed with state tables that map, for example, the gates of a D-latch from FIG. 3A or FIG. 3B into LUT 1202. That is, the 1-LUT polymorphic latch 1200 is implemented by using a single LUT, which may provide a more efficient implementation compared to using 2 LUTs, such as the 2-LUT polymorphic latch 1100.

Inputs I1 and I2 of LUT 1202 are connected to CLK and input D signals. In some embodiments, a polymorphic control signal is provided to input I3 of the LUT 1202. The polymorphic control signal may comprise a control signal used to switch between a specific mode of operation (e.g., normal operation or forbidden state) of the 1-LUT polymorphic latch 1200. In some embodiments, the I3 input is configured to receive a polymorphic control signal, wherein the polymorphic control signal is (i) used to trigger a forbidden state and (ii) generated based on an external trigger source, such as a voltage sensor or a temperature sensor. The O0 and O1 outputs of the LUT 1202 comprise latch signals Q and Q̅, that are representative of a value stored on a memory device comprising the 1-LUT polymorphic latch 1200. The outputs Q and Q̅ are provided as feedback to inputs I0 and I4 of the LUT 1202.

An example state table for the 1-LUT polymorphic latch is shown in Table 10.

TABLE 10

| Poly | Q₋ | Q̅₋ | CLK | D | Q₊ | Q̅₊ |
|---|---|---|---|---|---|---|
| 0 | 0 | 0 | X | X | 0 | 1 |
| 0 | 0 | 1 | 0 | X | 0 | 1 |
| 0 | 0 | 1 | 1 | 0 | 0 | 1 |
| 0 | 0 | 1 | 1 | 1 | 1 | 0 |
| 0 | 1 | 0 | 0 | X | 1 | 0 |
| 0 | 1 | 0 | 1 | 0 | 0 | 1 |
| 0 | 1 | 0 | 1 | 1 | 1 | 0 |
| 0 | 1 | 1 | 0 | X | 1 | 0 |
| 0 | 1 | 1 | 1 | 0 | 0 | 1 |
| 0 | 1 | 1 | 1 | 1 | 1 | 0 |
| 1 | X | X | X | X | 1 | 1 |

The forbidden state of the 1-LUT polymorphic latch 1200 may be customized on a per-latch basis to be either Q=Q̅=1 or Q=Q̅=0, which may be controlled by changing the bits programmed into the LUT state table for the Poly=1 row. The state in which the 1-LUT polymorphic latch 1200 returns when the Poly signal is de-asserted (e.g., the restoration state of the latch) may be controlled by changing the bits programmed for the row in the LUT state table where Poly=0 and Q=Q̅.

Thus, when a latch instance is in a forbidden state (e.g., Q=Q̅=1 forbidden state or Q=Q̅=0 forbidden state) but Poly is de-asserted, the contents may be restored to a specific, customizable value. Control of the restoration states in the 1-LUT polymorphic latch 1200 may comprise an advantage over a 2-LUT polymorphic latch's need for controlling feedback delays. Another advantage of the 1-LUT polymorphic latch 1200 is associated with programming the bits in the state table directly, instead of implementing predetermined logic gates thereby allowing a forbidden state to be mapped to both CLK=0 and CLK=1 states. In some embodiments, the 1-LUT polymorphic latch 1200 is configured to enter a forbidden state based on only on the Poly signal.

### Supporting Circuitry for LUT-Based Latches

The disclosed 1-LUT or 2-LUT polymorphic latches may also be combined with on-chip or external sensors to provide destructive logic-based memory in FPGAs. For example, a forbidden state may be triggered for either latch when the Poly input signal is driven high. As such, a sensor may be instantiated to drive the Poly signal high when the conditions of a physical attack are detected. The sensor may comprise a temperature and voltage sensor (TVS), such as a Xilinx XADC IP that includes a programmable internal voltage (VCCINT) alarm and a programmable temperature alarm. The VCCINT alarm and the programmable temperature alarm may be configured to drive a Poly signal to high when their respective conditions exceed a predetermined value. For example, the VCCINT alarm may be programmed to 0.9V to counter a TLS or LLSI attack. Simultaneously, the temperature alarm may be programmed to trigger when a device temperature reaches temperatures indicative of a laser-based attack. Accordingly, by making use of a TVS, both voltage and temperature may be monitored simultaneously and used to trigger LUT-based polymorphic latches.

Additionally, for a 2-LUT polymorphic latch, the CLK input may be held at ‘0’ in order for the forbidden state to be entered. In some embodiments, the latch clock source providing the CLK may be routed through clock gating logic, such as an AND logic gate with an inverted input, such that the CLK signal is not passed when an alarm driving the Poly signal is triggered.

### CONCLUSION

It should be understood that the examples and embodiments described herein are for illustrative purposes only and that various modifications or changes in light thereof will be suggested to persons skilled in the art and are to be included within the spirit and purview of this application.

Many modifications and other embodiments of the present disclosure set forth herein will come to mind to one skilled in the art to which the present disclosures pertain having the benefit of the teachings presented in the foregoing descriptions and the associated drawings. Therefore, it is to be understood that the present disclosure is not to be limited to the specific embodiments disclosed and that modifications and other embodiments are intended to be included within the scope of the appended claim concepts. Although specific terms are employed herein, they are used in a generic and descriptive sense only and not for purposes of limitation.

1. A polymorphic latch comprising:
a pair of polymorphic gates that is configured in a D-latch, wherein a polymorphic gate of the pair of polymorphic gates comprises:
(i) a low voltage function and a high voltage function,
(ii) a pull-down network (PDN) that is associated with the high voltage function,
(iii) a pull-up network (PUN) that is coupled to the PDN, wherein the PUN is associated with the low voltage function, and
(iv) one or more gating transistors that are configured to provide the PDN with a path to a ground;
a pair of AND logic gates, wherein an output of an AND logic gate of the pair of AND logic gates is coupled to an input of the polymorphic gate; and
an inverter coupled to an input of the AND logic gate.

2. The polymorphic latch of claim 1, wherein the low voltage function comprises a NAND gate operation.

3. The polymorphic latch of claim 2, wherein the NAND gate operation comprises a forbidden state that is associated with a low clock signal.

4. The polymorphic latch of claim 1, wherein the high voltage function comprises a NOR gate operation.

5. The polymorphic latch of claim 1, wherein the low voltage function comprises a function associated with providing a supply voltage to the pair of polymorphic gates, wherein the supply voltage is below a threshold voltage.

6. The polymorphic latch of claim 1, wherein the high voltage function comprises a function associated with providing a supply voltage to the pair of polymorphic gates, wherein the supply voltage is above a threshold voltage.

7. The polymorphic latch of claim 1, wherein the pair of polymorphic gates comprises a pair of two bistable feedback gates.

8. The polymorphic latch of claim 1 further comprising a polymorphic clock buffer/constant-off gate that is coupled to a clock input that is received by the pair of AND logic gates.

9. The polymorphic latch of claim 8, wherein the polymorphic clock buffer/constant-off gate is configured to generate logic zero based on a supply voltage that is provided to the pair of polymorphic gates, wherein the supply voltage is below a threshold voltage.

10. A polymorphic register comprising:
a first polymorphic latch comprising a first data input and a first data output;
a second polymorphic latch comprising a second data input and a second data output, wherein the first data output is coupled to the second data input;
wherein the first polymorphic latch or the second polymorphic latch comprises a low voltage function and a high voltage function.

11. The polymorphic register of claim 10, wherein:
(i) the low voltage function comprises a first logic gate functionality;
(ii) the high voltage function comprises a second logic gate functionality, and
(iii) the first logic gate functionality is different from the second logic gate functionality.

12. The polymorphic register of claim 10, wherein the low voltage function is associated with providing a supply voltage to the first polymorphic latch or the second polymorphic latch, wherein the supply voltage is below a threshold voltage.

13. The polymorphic register of claim 10, wherein the high voltage function is associated with providing a supply voltage to the first polymorphic latch or the second polymorphic latch, wherein the supply voltage is above a threshold voltage.

14. The polymorphic register of claim 10, wherein the first polymorphic latch or the second polymorphic latch comprises a pair of polymorphic gates.

15. The polymorphic register of claim 10, wherein the first polymorphic latch or the second polymorphic latch comprises at least one lookup table.

16. A polymorphic latch comprising:
at least one lookup table that is configured with a state table, wherein the state table is associated with a D-latch that comprises:
(i) a pair of polymorphic gates that is configured as two bistable feedback gates,
(ii) an inverter, and
(iii) a pair of AND logic gates, wherein:
(a) an AND logic gate of the pair of AND logic gates comprises a clock signal input and (1) a data input or (2) an inverted data input,
(b) the inverted data input is provided by the inverter,
(c) an AND logic gate output of the pair of AND logic gates is coupled to a respectively corresponding polymorphic gate input of a polymorphic gate of the pair of polymorphic gates, and
(d) the D-latch is configured to generate a D-latch output based on a polymorphic gate output of the polymorphic gate.

17. The polymorphic latch of claim 16, wherein the at least one lookup table is configured to receive a polymorphic control signal that is associated with a mode of operation.

18. The polymorphic latch of claim 17, wherein the polymorphic control signal is (i) used to trigger a forbidden state and (ii) generated based on a voltage sensor or a temperature sensor.

19. The polymorphic latch of claim 17, wherein the at least one lookup table is coupled to a sensor that is configured to provide the polymorphic control signal.

20. The polymorphic latch of claim 16, wherein the D-latch output is provided to a feedback input of the polymorphic gate.
